(19) United States
(12) Patent Application Publication
(10) Pub. No.: US 2006/0234498 A1
(43) Pub. Date: Oct. 19, 2006

(54) Method of performing a surface treatment respectively on the via and the trench in a dual damascene process

(76) Inventor: Qiang Guo, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/107,966

(22) Filed: Apr. 18, 2005

(51) Int. Cl. H01L 21/4763

(52) U.S. Cl. 438/638; 438/710

(57) ABSTRACT

The present invention provides a method of performing a surface treatment respectively on the via and the trench in a dual damascene process by the plasma having the inclined angle. The residual and/or the metal surface oxide on the bottom of the via are removed in the via and the trench etching process, and the surface treatment is performed on the surface of the trench, thereby preventing the poor electrical and increasing the adhesive force between the surface of the trench and the barrier metal layer, resulting in solving the disadvantage which the surface treatment can not be respectively performed and the trench according to the prior art.

### BACKGROUND OF THE INVENTION

1. Field of the Invention

The present invention relates to a surface treatment method of the dual damascene process, more particularly, to a method of performing a surface treatment respectively on the via and the trench in a dual damascene process.

2. Description of the Prior Art

In the dual damascene process, when completed the via and the trench etching process, a surface treatment process is needed to be perform, in order to remove the residual and/or the metal surface oxide in the via and to increase the adhesive force between the barrier layer and the intermetal dielectric layer.

In the current technology, there are two method of performing the surface treatment. One is an isotropic plasma, as shown in FIG. 1, and another is one-way plasma, as shown in FIG. 2. In the isotropic plasma, the moving direction of the ion is out of order. Therefore, the bottom of the via 12 and the surface of the trench 10 are simultaneously subjected by the reaction of the plasma ion. In the one-way plasma, the ion is moved in one direction. The ion movement is perpendicular to the bottom of the via 12 and the surface of the trench 10, and the bottom of the via 12 and the surface of the trench 10 are simultaneously subjected by the reaction of the plasma ion. These two plasma surface treatment can not suited the practical requirement. The materials of the bottom of the via 12 and the surface of the trench 10 are different. These treatments are also different. For examples, the material of the bottom of the via is metal, and the treatment is performed to clean the residual on the surface and/or increase the adhesive force between the barrier metal layer and the dielectric layer. Obviously, the current technology can not satisfy this requirement.

In view of the above problems, the present invention provides a method of performing a surface treatment respectively on the via and the trench in a dual damascene process.

### SUMMARY OF THE INVENTION

The present invention provides a method of performing a surface treatment respectively on the via and the trench in a dual damascene process, which the surface treatment is respectively performed on the bottom of the via and the surface of the trench based on the different requirements of the surface status of the via and the trench.

The present invention also provides a method of performing a surface treatment respectively on the via and the trench in a dual damascene process, which discloses a method of performing the surface treatment on the via and the trench in a dual damascene process by using the plasma having the inclined angle, because the inclined angle of the plasma is adjusted based on the ratio of the via and the trench, thereby providing a more free surface treatment method.

The present invention also provides a method of performing a surface treatment respectively on the via and the trench in a dual damascene process, thereby obtaining the better status of the via bottom and the trench surface.

To achieve the aforementioned objects and more, a preferred embodiment of the present invention provides a method of performing a surface treatment respectively on the via and the trench in a dual damascene process, comprising: providing a semiconductor substrate having integrated circuits, forming a metal layer, an intermetal dielectric layer thereon sequentially, and wherein a via and a trench are sequentially formed on the intermetal dielectric layer; performing a first plasma surface treatment on a bottom of the via; and performing a second plasma surface treatment on a surface of the trench, and a forward direction of an ion beam is at an angle to the normal of the bottom of the via while performing the second surface treatment.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

In the drawings,

FIG. 1 and FIG. 2 illustrate that a surface treatment is performed on the via and the trench in a dual damascene process by using a plasma according to the prior art;

FIG. 3 is a partially cross-sectional view showing the structure of the via and the trench in the semiconductor substrate after completed a copper damascene process according to the present invention;

FIG. 4 is a cross-sectional view showing the apparatus according to the present invention;

FIG. 5 illustrates that a surface treatment is performed on the bottom of the via according to the present invention; and

FIG. 6 illustrates that a surface treatment is performed on the surface of the trench according to the present invention.

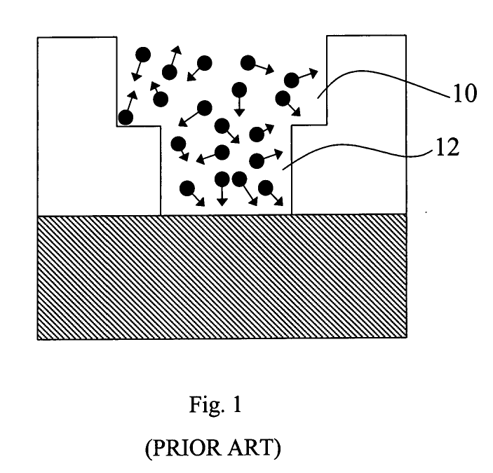

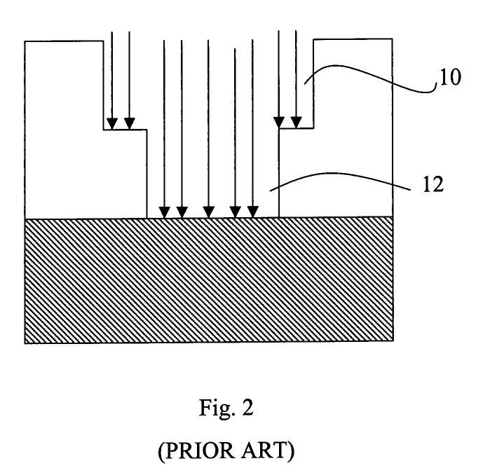

### DETAILED DESCRIPTION OF THE PREFERRED EMBODIMENTS

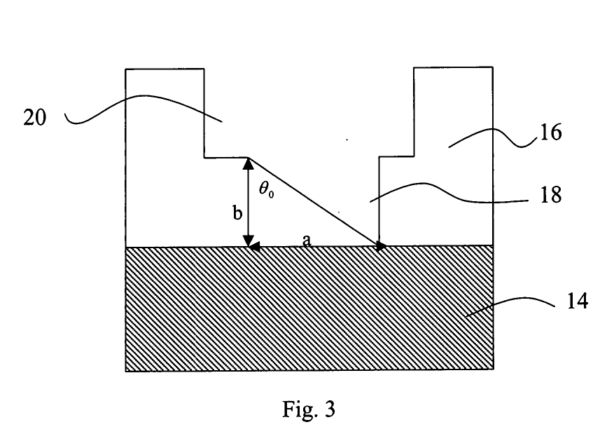

The present invention provides a method of performing a pre-separated treatment respectively on the via and the trench in a dual damascene process. As shown in FIG. 3, a semiconductor substrate (not shown in the drawing) having the foundation devices (such as integrated circuits) formed thereon is provided. A metal layer 14 and an intermetal dielectric layer 16 are sequentially formed on the semiconductor substrate. A dual damascene process is performed on the semiconductor substrate to form a via 18 and a trench 18 having a bottom width a and a neck portion length b in the intermetal dielectric layer 16, in order to complete the dual damascene process. The etching step and the etch stop layer of the dual damascene process which are not the points in the present invention are omitted.

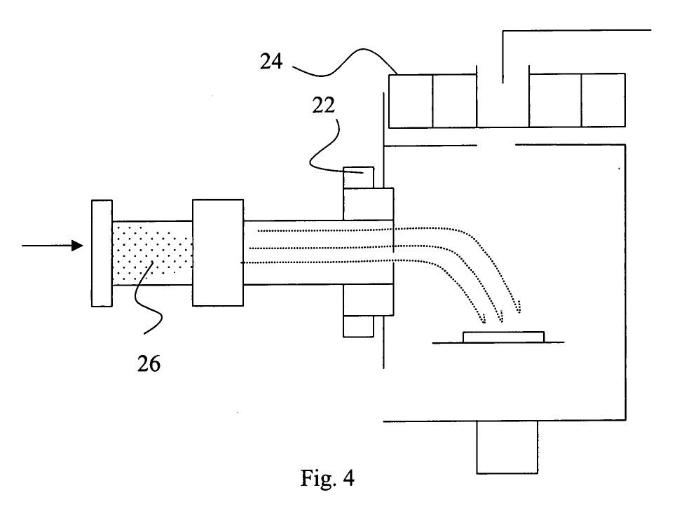

Next, the value of a specific angle θ₀, which is obtained by tan θ₀=a/b, is obtained by the value a and b. As shown in FIG. 3, when the direction of the plasma is at an inclined angle, a plasma apparatus separated by a longer distance is used, as shown in FIG. 4, in order to control the magnetic force magnitude of the emitting electromagnetism 22 and operate the electromagnetism to determine a deflection angle generated by the gas ion plasma 26 after the dissociation. Therefore, the present invention provides a method which pre-separated surface treatment is performed on surface of the via 18 and the trench 20 in the dual damascene process by using the plasma beam with the inclined angle.

Next, a process recipe is set. First, the process recipe is set based on the requirement of the bottom of the via 18. A first plasma surface treatment is then performed on the wafer. The process recipe is set based the requirement of the surface of the trench 20. A second plasma surface treatment is then performed on the wafer.

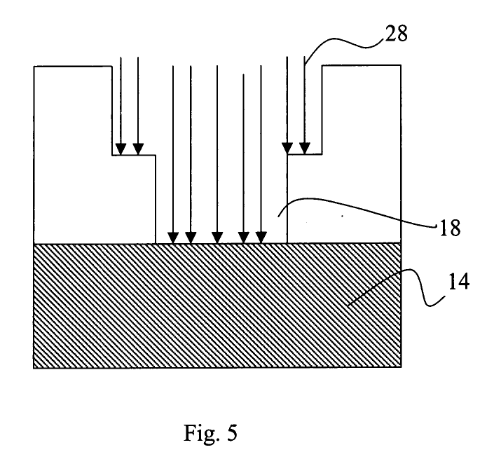

When the surface treatment is performed on the bottom of the via and the surface of the trench according to the present invention, a surface treatment is performed on the bottom of the via 18 first. The surface treatment is performed by using the one-way or same-way plasma based on the process requirement. As shown in FIG. 5, an one-way plasma is used to remove the residual and the oxide layer on the bottom of the via 18 in the etching process, thereby preventing the poor electric conductivity from the metal layer and the oxide layer or residual.

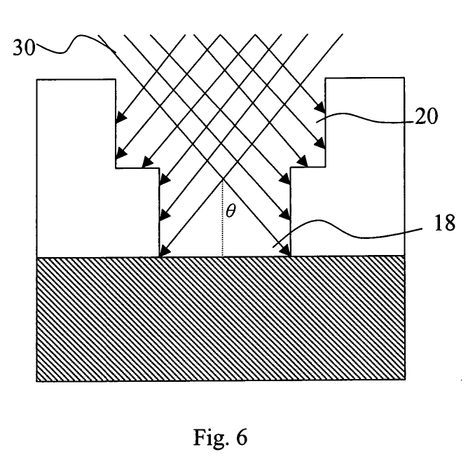

Additional, based on the requirement of the surface of the trench 20, as shown in FIG. 6, the plasma 30 having an angle θ relative to the ion bombardment direction and the normal of the bottom of the via performs a surface treatment on the trench 20 and the wafer is rotated at the same time. Since the angel relative to the ion moving direction generated by the plasma 30 and the normal direction of the bottom of the via 18 is larger than θ₀ or equal to θ₀, the ion of the plasma can not reach the bottom of the via 18, resulting in reducing opportunity of the bottom of the via 18 reacted by the plasma ion. Therefore, the surface treatment is performed on the obtained better trench, thereby obtaining the better adhesive force between the barrier metal (not showing in the drawing) deposited on the surface of the trench 20 and the surface of the trench 20 in the consequent process. The surface treatment is performed on the surface to be treated based on the magnitude of the angle θ.

By controlling the magnetic force magnitude of the emitting electromagnetism 22 and operating the electromagnetism, a deflection angle generated by the gas ion plasma 26 is determined after the dissociation, thereby enlarging the probability of the treated wafer surface subjected by using the plasma to perform a surface treatment by using the plasma beam having the inclined angle. Therefore, the present invention also applies on the other surface treatment which requires the plasma.

The embodiment above is only intended to illustrate the present invention; it does not, however, to limit the present invention to the specific embodiment. Accordingly, various modifications and changes may be made without departing from the spirit and scope of the present invention as described in the following claims.

What is claimed is:

1. A method of performing a surface treatment respectively on a via and a
trenches in a dual damascene process, comprising:
providing a semiconductor substrate having integrated circuits, forming a metal layer, an intermetal dielectric layer thereon sequentially, and wherein a via and a trench are sequentially formed on the intermetal dielectric layer;
performing a first plasma surface treatment on a bottom of the via; and
performing a second plasma surface treatment on a surface of the trench, and a forward direction of an ion beam is at an angle to the normal of the bottom of the via while performing the second surface treatment.

2. The method of performing a surface treatment respectively on a via and a trenches in a dual damascene process of claim 1, wherein the tangent value of the angle is larger than a value which is obtained by the numerator being the width of the bottom of the via and the denominator being the length of a neck portion of the via.

3. The method of performing a surface treatment respectively on a via and a trenches in a dual damascene process of claim 1, wherein a plasma of the second plasma surface treatment is generated by using a plasma apparatus separated by a longer distance.

4. The method of performing a surface treatment respectively on a via and a trenches in a dual damascene process of claim 3, wherein the plasma apparatus is used by the magnetic force magnitude controlled by a controlled emitting electromagnetism and a operated electromagnetism to determine a deflection angle generated by the gas ion plasma after the dissociation.

5. The method of performing a surface treatment respectively on a via and a trenches in a dual damascene process of claim 1, wherein the first plasma surface treatment is performed to remove the oxide on the surface of the metal layer.

6. The method of performing a surface treatment respectively on a via and a trenches in a dual damascene process of claim 1, wherein the via and the trench are formed by an etching process.

7. The method of performing a surface treatment respectively on a via and a trenches in a dual damascene process of claim 6, wherein the first plasma surface treatment is performed to remove the residual on the surface of the metal layer after the etching process.

8. The method of performing a surface treatment respectively on a via and a trenches in a dual damascene process of claim 1, wherein after the second plasma surface treatment, a barrier metal layer is deposited in the trench and the via.

9. The method of performing a surface treatment respectively on a via and a trenches in a dual damascene process of claim 1, wherein the second plasma surface treatment is performed to increase the adhesive force between the barrier metal layer and the surface of the trench.

10. The method of performing a surface treatment respectively on a via and a trenches in a dual damascene process of claim 6, wherein the second plasma surface treatment is performed to clean the residual on the surface of the trench.
